(19) United States
(12) Patent Application Publication
(10) Pub. No.: US 2004/0180553 A1
(43) Pub. Date: Sep. 16, 2004

(54) Method of depositing ALD thin films on wafer

(76) Inventors: Young Hoon Park, Pyungtaek-city (KR); Keun Jae Yoo, Pyungtaek-city (KR); Sang Kwon Park, Pyungtaek-city (KR); Byung Chul Cho, Pyungtaek-city (KR); Seoung Wook Lee, Pyungtaek-city (KR); Hong Joo Lim, Pyungtaek-city (KR); Sang Kyu Lee, Pyungtaek-city (KR)

Correspondence Address: Michael A. Cantor, 55 Giffin South Road, Bloomfield, CT, 06002, US

(21) Appl. No.: 10/798,144

(22) Filed: Mar. 10, 2004

(30) Foreign Application Priority Data
Mar. 13, 2003 (KR) 2003-15718

(51) Int. Cl. H01L 21/31; H01L 21/4763; H01L 21/469

(52) U.S. Cl. 438/758; 438/785

(57) ABSTRACT

Provided is a method of depositing an ALD thin film. The method includes (S1) loading a wafer on a wafer block; (S2) depositing the ALD thin film on the wafer; (S3) unloading the wafer, on which the ALD thin film is deposited, from the wafer block; (S4-1) loading a dummy wafer on the wafer block; (S4-2) stabilizing the flow rates and the pressures of gases in the reactor by spraying only an inert gas or a mixture of the inert gas and a cleaning gas in the reactor; (S4-3) supplying RF power to the showerhead so as to activate the cleaning gas and mostly removing a thin film deposited on a surface of the showerhead by using the activated cleaning gas; (S4-4) unloading the dummy wafer from the wafer block; (S4-5) repeating steps 4-1 through 4-4 at least once using new dummy wafers; and (S5) purging the inside of the reactor.

This application claims the priority of Korean Patent Application No. 2003-15718, filed on Mar. 13, 2003, in the Korean Intellectual Property Office, the disclosure of which is incorporated herein by reference in their entirety.

### BACKGROUND OF THE INVENTION

1. Field of the Invention

The present invention relates to a method of more efficiently depositing atomic layer deposition (ALD) thin films.

2. Description of the Related Art

In recent years, to improve the productivity of semiconductor chips, semiconductor manufacturers have been competing to increase the diameter of wafers and decrease the linewidth of circuits, and have been considering various factors, such as a footprint, which is an area occupied by a thin film deposition apparatus, the price of the thin film deposition apparatus, the rate of operation of equipment, the maintenance cost, and the number of processed wafers per unit of time. Cost of ownership (CoO) is an index that summarizes the above-described factors, and lowering the CoO cost is important for the productivity of semiconductor chips.

A dry cleaning process is one of the most important techniques that greatly affects the CoO cost. The dry cleaning process is to remove byproducts deposited in a reactor during deposition of thin films. Whether or not dry cleaning is effectively performed without opening the reactor is important for lowering the CoO cost. Thus, expansive research on the dry cleaning has been performed.

### SUMMARY OF THE INVENTION

The present invention provides a method of depositing an ALD thin film, the method which allows effective dry cleaning by using radio frequency (RF) power.

According to an aspect of the present invention, there is provided a method of depositing an ALD thin film. The method is performed using a thin film deposition apparatus, comprising a reactor comprising a wafer block disposed in a chamber, the wafer block which heats a loaded wafer to a predetermined temperature, a top lid which covers and seals the chamber, a showerhead disposed under the top lid and combined with the top lid such that the showerhead is electrically isolated from the top lid, the showerhead including first spray holes and second spray holes, through which a first reaction gas and a second reaction gas are respectively sprayed on the wafer; and one or more RF power supply units which supply RF power to only the showerhead or both the showerhead and the wafer block. The method of depositing an ALD thin film comprises (S1) loading the wafer on the wafer block; (S2) depositing the ALD thin film on the wafer; (S3) unloading the wafer, on which the ALD thin film is deposited, from the wafer block; (S4-1) loading a dummy wafer on the wafer block; (S4-2) stabilizing the flow rates and the pressures of gases in the reactor by spraying only an inert gas or a mixture of the inert gas and a cleaning gas in the reactor; (S4-3) supplying RF power to the showerhead so as to activate the cleaning gas and mostly removing a thin film deposited on a surface of the showerhead by using the activated cleaning gas; (S4-4) unloading the dummy wafer from the wafer block; (S4-5) repeating steps 4-1 through 4-4 at least once using new dummy wafers; and (S5) purging the inside of the reactor.

According to another aspect of the present invention, there is provided a method of depositing an ALD thin film. The method is performed using a thin film deposition apparatus, comprising a reactor comprising a wafer block disposed in a chamber, the wafer block which heats a loaded wafer to a predetermined temperature, a top lid which covers and seals the chamber, a showerhead disposed under the top lid and combined with the top lid such that the showerhead is electrically isolated from the top lid, the showerhead including first spray holes and second spray holes, through which a first reaction gas and a second reaction gas are respectively sprayed on the wafer; and one or more RF power supply units which supply RF power to only the showerhead or both the showerhead and the wafer block. The method of depositing an ALD thin film comprises (S1) loading the wafer on the wafer block; (S2) depositing the ALD thin film on the wafer; (S3) unloading the wafer, on which the ALD thin film is deposited, from the wafer block; (S3.5) reducing the temperature of the wafer block to be lower than when the ALD thin film is deposited; (S4-1) loading a dummy wafer on the wafer block of which the temperature is reduced; (S4-2) stabilizing the flow rates and the pressures of gases in the reactor by spraying only an inert gas or a mixture of the inert gas and a cleaning gas in the reactor; (S4-3) supplying RF power to the showerhead so as to activate the cleaning gas and mostly removing a thin film deposited on a surface of the showerhead by using the activated cleaning gas; (S4-4) unloading the dummy wafer from the wafer block; (S4-5) repeating steps 4-1 through 4-4 at least once using new dummy wafers; and (S5′) raising the temperature of the wafer block to the same temperature as the temperature when the ALD thin film is deposited, while purging the inside of the reactor using the inert gas.

The thin film deposition apparatus can further comprise a plurality of gas curtain holes disposed on lateral surfaces of the showerhead or the top lid, and the gas curtain holes spray the inert gas toward an inner wall of the reactor. Herein, step 2 can be performed while a gas curtain is being formed around the inner wall of the reactor by spraying the inert gas via the gas curtain holes.

The thin film deposition apparatus can further comprise a plurality of gas curtain holes disposed on lateral surfaces of the showerhead or the top lid, and the gas curtain holes spray the inert gas toward an inner wall of the reactor. Herein, step 4-3 can be performed while the cleaning gas is being sprayed via any one group of holes among the first spray holes, the second spray holes, and the gas curtain holes, and the inert gas is being sprayed via the remaining holes.

In step 4-3, the RF power can be discontinuously supplied to the showerhead to prevent the showerhead from overheating.

The method of the present invention can further comprise (S4′-3) supplying RF power to the wafer block so as to activate the cleaning gas and mostly removing a thin film deposited on a surface of the wafer block by using the activated cleaning gas. Herein, step 4′-3 can be performed during or after step 4-3.

The method of the present invention can further comprise (S6) adhering byproducts generated in step 4-3 and/or step 4′-3 to an inner surface of the reactor. Herein, step 6 can comprise a first pre-coating step performed before the dummy wafer is loaded on the wafer block; and a second pre-coating step performed after the dummy wafer is loaded on the wafer block.

### BRIEF DESCRIPTION OF THE DRAWINGS

The above object and advantages of the present invention will become more apparent by describing in detail exemplary embodiments thereof with reference to the attached drawings in which:

FIG. 1 is a front view of a first example of a thin film deposition apparatus for performing a method of depositing thin films according to the present invention;

FIG. 2 is a front view of a second example of a thin film deposition apparatus for performing the method according to the present invention;

FIG. 3 is a front view of a third example of a thin film deposition apparatus for performing the method according to the present invention;

FIG. 4 is a graph showing a method of depositing thin films according to an embodiment of the present invention, the method which is performed in the thin film deposition apparatus of FIGS. 1 through 3;

FIG. 5 is a graph showing RF power versus a time when RF power is discontinuously supplied to a showerhead in the method shown in FIG. 4;

FIG. 6 is a flowchart illustrating a process of cleaning the showerhead in the method shown in FIG. 4;

FIG. 7 is a flowchart illustrating a process of cleaning a wafer block in the method shown in FIG. 4;

FIG. 8 illustrates why the wafer block should be cleaned as shown in FIG. 7;

FIG. 9 is a graph showing the etch rate versus RF power supplied to the showerhead;

FIG. 10 is a graph showing the etch rate versus the pressure of cleaning gas;

FIG. 11 is a graph showing the etch rate versus the temperature of the wafer block;

FIG. 12 is a graph showing the etch uniformity versus the temperature of the wafer block;

FIG. 13 is a graph showing the etch uniformity versus the pressure of the cleaning gas;

FIG. 14 is a table summarizing the etch rate and etch uniformity shown in FIGS. 9 through 13;

FIG. 15 is a graph showing a method of depositing thin films according to another embodiment of the present invention, the method which is performed in the thin film deposition apparatus shown in FIGS. 1 through 3;

FIG. 16 is a graph showing a method of depositing thin films according to yet another embodiment of the present invention, the method which is performed in the thin film deposition apparatus shown in FIGS. 1 through 3;

FIG. 17 is a flowchart illustrating a process of cleaning a showerhead and a wafer block in the method shown in FIG. 16; and

FIG. 18 is a graph showing a method of depositing thin films according to further another embodiment of the present invention, the method which is performed in the thin film deposition apparatus shown in FIGS. 1 through 3.

### DETAILED DESCRIPTION OF THE INVENTION

The present invention will now be described more fully with reference to the accompanying drawings, in which exemplary embodiments of the invention are shown.

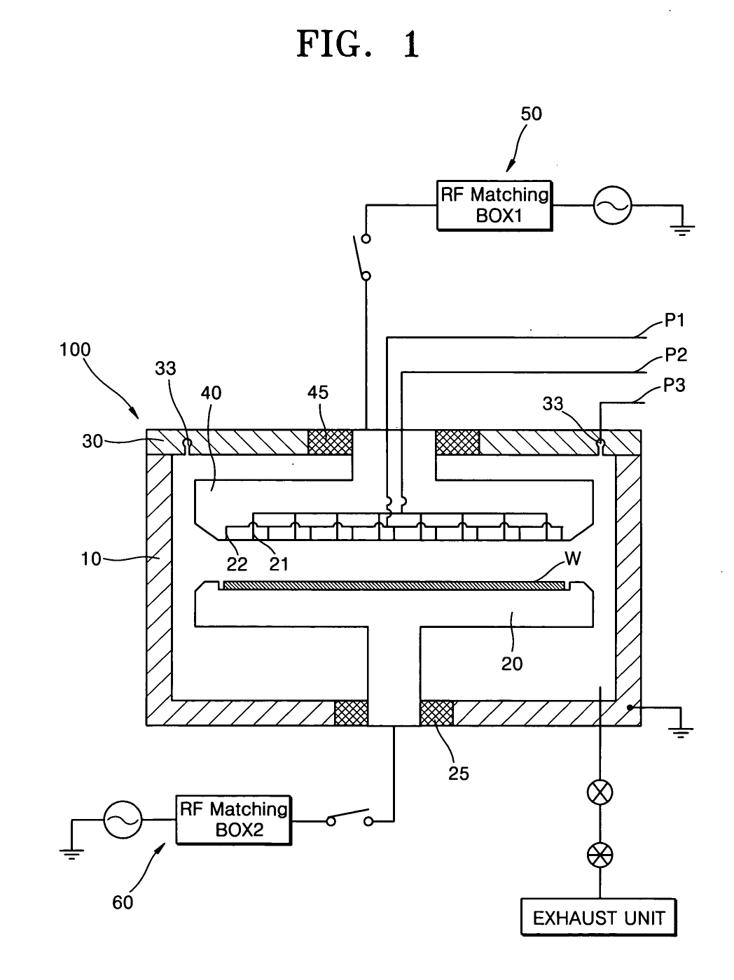

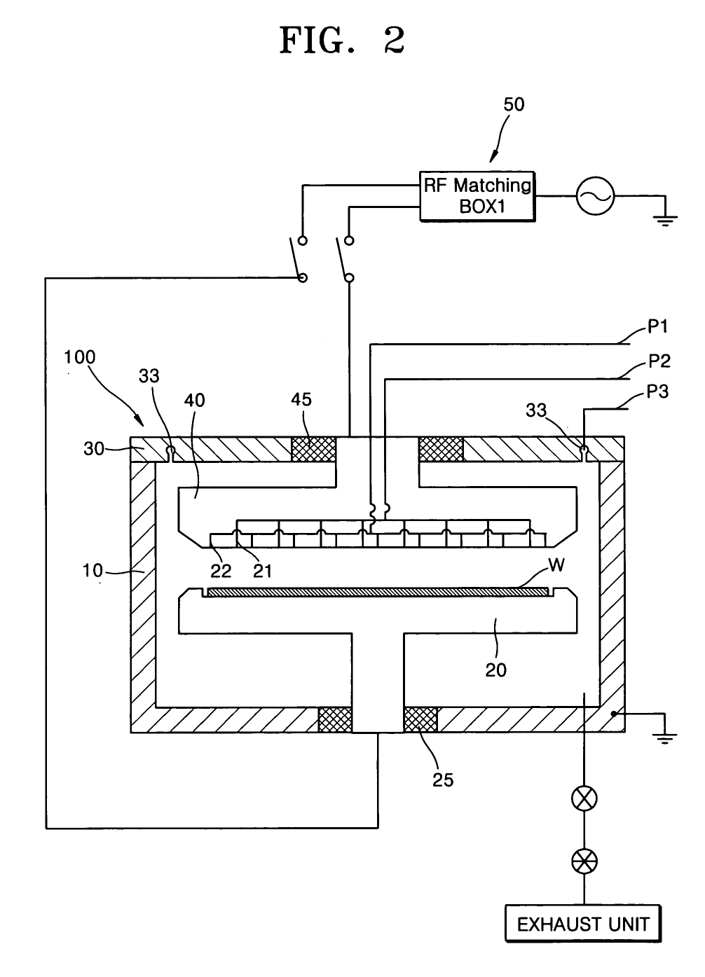

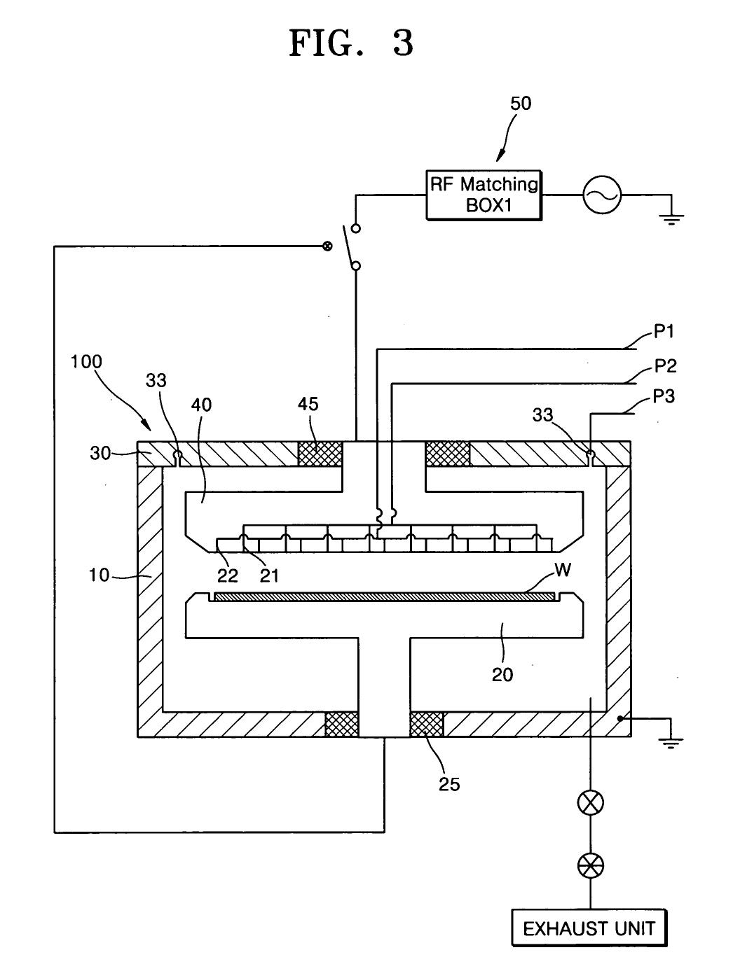

FIG. 1 is a front view of a first example of a thin film deposition apparatus for performing a method of depositing thin films according to the present invention, FIG. 2 is a front view of a second example of a thin film deposition apparatus for performing the method according to the present invention, and FIG. 3 is a front view of a third example of a thin film deposition apparatus for performing the method according to the present invention.

Referring to FIGS. 1 through 3, a thin film deposition apparatus has a reactor 100, which comprises a wafer block 20, a top lid 30, and a showerhead 40. The wafer block 20 is disposed inside a chamber 10 and heats a wafer W loaded in the chamber 10 to a predetermined temperature. The top lid 30 covers and seals the chamber 10. The showerhead 40 is disposed below the top lid 30 and combined with the top lid 30 but electrically isolated from the top lid 30 by a first insulator 45. The showerhead 40 sprays a first reaction gas and a second reaction gas on the wafer W. A spray surface is formed on a bottom surface of the showerhead 40 parallel to the wafer W, and a plurality of first spray holes 21 and a plurality of second spray holes 22 are formed in the spray surface of the showerhead 40. The first spray holes 21 and the second spray holes 22 are used to spray the first reaction gas and the second reaction gas, respectively, and are formed at regular intervals. The wafer block 20 is electrically isolated from the chamber 10 by a second insulator 25.

A method of depositing thin films according to the present invention can be performed in various reactors according to the type of a method of supplying RF power. For example, in the thin film deposition apparatus shown in FIG. 1, two RF power supply units 50 and 60 can supply RF power to the showerhead 40 and the wafer block 20, respectively. The apparatus shown in FIG. 2 comprises a single RF power supply unit 50, which can supply RF power to the showerhead 40 and the wafer block 20 at the same time. Also, the apparatus shown in FIG. 3 comprises a single RF power supply unit 50, which can supply RF power to any one of the showerhead 40 and the wafer block 20.

As described above, the structure of the thin film deposition apparatus is varied according to the type of a method of connecting one or more RF power supply units to the showerhead 40 and/or the wafer block 20. Thus, the RF power supply units can supply RF power to only the showerhead 40 or both the showerhead 40 and the wafer block 20.

A plurality of gas curtain holes 33 are formed in the top lid 30. The gas curtain holes 33 spray an inert gas supplied from a third connection line P3 toward inner sidewalls of the reactor 100 outside the wafer block 20. The gas curtain holes 33 may be used to spray a cleaning gas during a cleaning process. Although the gas curtain holes 33 are formed in the top lid 30 in the present embodiment, it is possible to form the gas curtain holes 33 in lateral surfaces of the showerhead 40.

The first spray holes 21 and the second spray holes 22, formed in the bottom surface of the showerhead 40, spray the first reaction gas and the second reaction gas, respectively, on the wafer block 20. The first reaction gas and the second reaction gas are alternately supplied from a first connection line P1 and a second connection line P2, respectively. The first spray holes 21 are not connected to the second spray holes 22 in the showerhead 40.

A method of depositing thin films according to an embodiment of the present invention, which is performed in the above-described thin film deposition apparatus, will now be described.

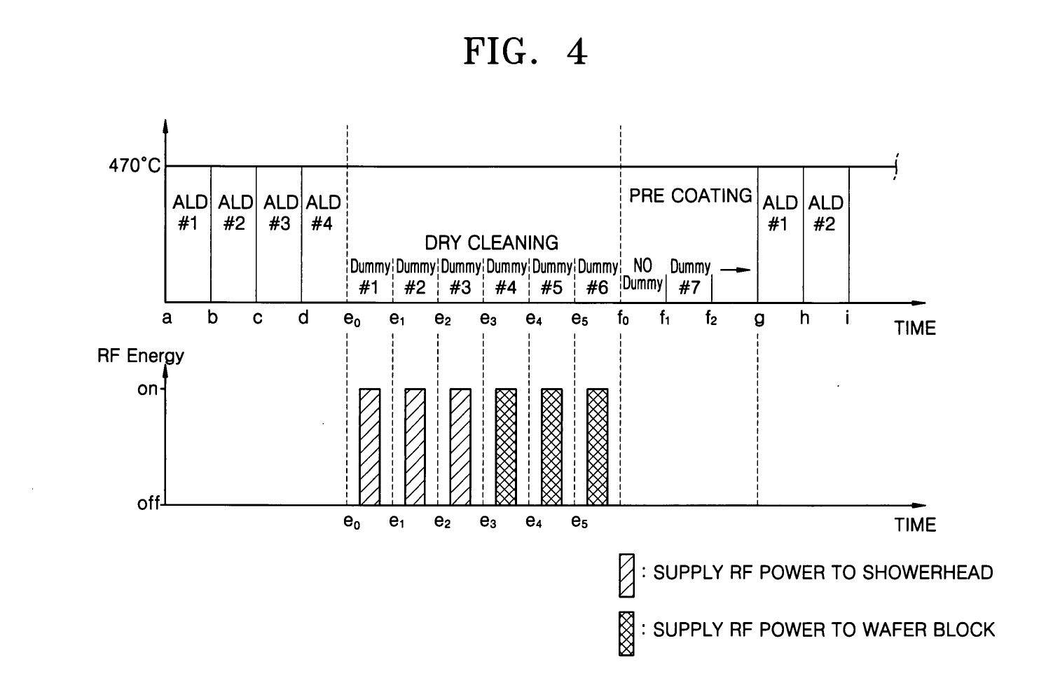

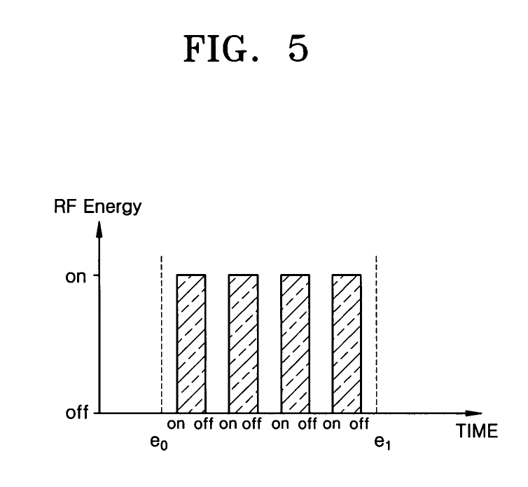

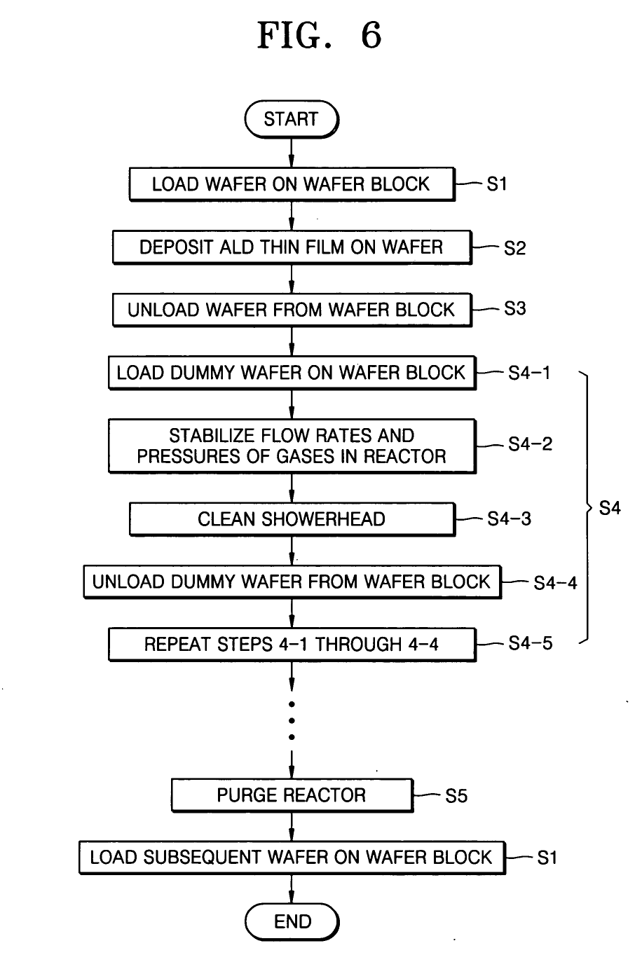

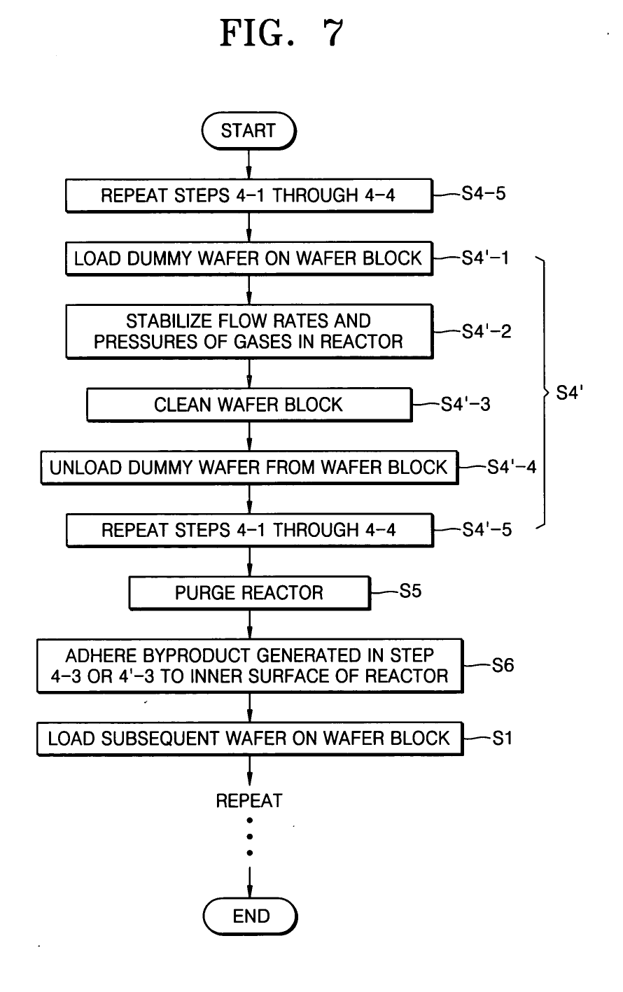

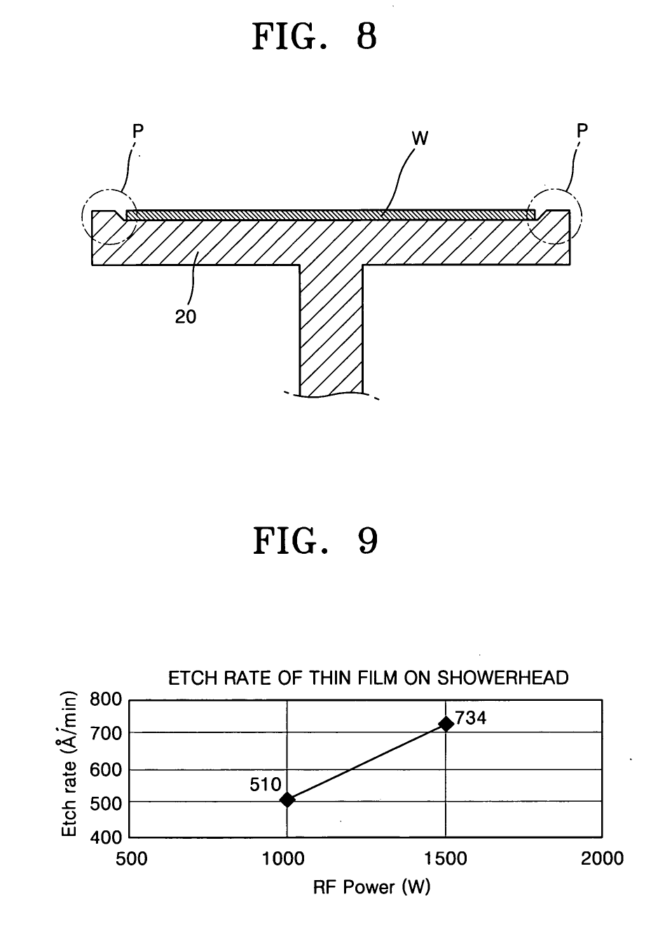

FIG. 4 is a graph showing a method of depositing thin films according to an embodiment of the present invention, which is performed in the thin film deposition apparatus of FIGS. 1 through 3, FIG. 5 is a graph showing RF power versus time when RF power is discontinuously supplied to a showerhead in the method shown in FIG. 4, FIG. 6 is a flowchart illustrating a process of cleaning the showerhead in the method shown in FIG. 4, FIG. 7 is a flowchart illustrating a process of cleaning a wafer block in the method shown in FIG. 4, and FIG. 8 illustrates why the wafer block should be cleaned as shown in FIG. 7.

Referring to FIGS. 6 and 7, in step 1, the wafer W is loaded on the wafer block 20. An ALD thin film is deposited on the wafer W in step 2, and then the wafer W on which the ALD thin film is deposited is unloaded from the wafer block 20 in step 3. In step S4 and/or S4′, the showerhead 40 and/or the wafer block 20 is dry cleaned by spraying a cleaning gas into the reactor 100. Thereafter, the inside of the reactor 100 is purged using an inert gas in step 5, and particles, which remain on an inner surface of the reactor 100 as byproducts of the cleaning process, are coated on the inner surface of the reactor 100 in step 6.

Referring to FIG. 4, steps 1, 2, and 3 are performed during a period between a and e₀ and after the period g when the first and second spray holes 21 and 22 alternately spray the first reaction gas and the second reaction gas on the wafer W loaded on the wafer block 20, such that an ALD thin film is deposited on the wafer W.

In FIG. 4, #1, #2, #3, and #4 are each an example of the number of repeated depositions of thin films, and the number of repeated depositions of thin films depends on the number of loaded wafers. For example, when an Al₂O₃ thin film is deposited, the inside of the reactor 100 is maintained at a temperature of about 470° C. and a wafer W heats up to a temperature of about 450° C. A final wafer W on which the ALD thin film is deposited is unloaded from the wafer block 20 and the reactor 100 directly before the dry cleaning process.

While a thin film is being deposited, an inert gas is sprayed via the gas curtain holes 33 formed in the top lid 30 or the lateral surface of the showerhead 40 toward inner sidewalls of the reactor 100 to form a gas curtain. The gas curtain minimizes the amounts of the first and second reaction gases that contact the inner sidewalls of the reactor 100, thus preventing deposition of an undesired thin film on the inner sidewalls of the reactor 100.

An ALD thin film deposited on the wafer W through the foregoing steps can be formed of one selected from the group consisting of Al₂O₃, HfO₂, and ZrO₂.

The dry cleaning step comprises step 4 performed during a period between e0 and e3 and step 4′ performed during a period between e3 and f0. In step 4, a thin film deposited on the showerhead 40 is mostly cleaned, and in step 4′, a thin film deposited on an edge of the wafer block 20 is mostly cleaned.

To perform step 4, the final wafer on which the ALD thin film is deposited is unloaded from the wafer block 20 and a subsequent dummy wafer is loaded on the wafer block 20 in step 4-1. Next, in step 4-2, a pre-conditioning step, the flow rates and the pressures of the gases in the reactor 100 are stabilized. In step 4-3, plasma is generated by supplying RF power to the showerhead 40 to activate a cleaning gas. The activated cleaning gas mostly removes the thin film deposited on a surface of the showerhead 40 in the reactor 100. Thereafter, the dummy wafer is unloaded from the wafer block 20 in step 4-4. Then, in step 4-5, steps 4-1 through 4-4 are repeated at least once using new dummy wafers. In the present embodiment, steps 4-1 through 4-4 are repeated three times. After step 4-5, the final dummy wafer is unloaded from the wafer block 20, and the inside of the reactor 100 is purged using an inert gas.

More specifically, in step 4-1, a dummy wafer where no patterns are formed is loaded on the wafer block 20. During dry cleaning, a cleaning gas is activated by direct plasma generated in the reactor 100 and may collide with the surface of the wafer block 20. Also, particles of the cleaned thin film are sputtered from the showerhead 40 and may be redeposited on the surface of the wafer block 20. Thus, to prevent damage of the wafer block 20 and redeposition of the particles, the dummy wafer is loaded on the wafer block in step 4-1.

In step 4-2, the flow rates and pressures of the gases in the reactor 100 are stabilized by spraying an inert gas or a mixture of a cleaning gas and an inert gas in the reactor 100. To remove a thin film formed of Al₂O₃, HfO₂, or ZrO₂, which is not sufficiently cleaned using conventional thermal dry cleaning, BCl₃ gas is used as a cleaning gas and Ar or N₂ gas is used as an inert gas. The BCl₃ gas is supplied at a flow rate of about 5 sccm to 1000 sccm, and the inert gas is supplied at a flow rate of about 5 sccm to 1000 sccm. The reactor 100 is maintained under a pressure of about 2 Torr or less.

In step 4-3, RF power is supplied to the showerhead 40 in the reactor 100 in which the flow rates and the pressures of gases remain constant. The RF power has a frequency of 13.56 MHz, and plasma is generated in the reactor 100 by the supplied reaction gas. Ingredients of the cleaning gas are activated by the plasma and collide with the showerhead 40 such that a thin film deposited on the showerhead 40 is separated from the showerhead 40.

Since a large portion of the thin film is deposited on the showerhead 40 in the reactor 100, dry cleaning of the showerhead 40 determines the dry cleaning cycle. Thus, reliable dry cleaning of the showerhead 40 significantly affects the efficiency of the dry cleaning of the reactor 100.

When the showerhead 40 is dry cleaned, the RF power supplied to the showerhead 40 is the most important factor that determines the etch rate of the thin film deposited on the showerhead 40. Next, the etch rate of the thin film depends on a composition rate of the cleaning gas and the inert gas or the pressure of the cleaning gas for dry cleaning. Preferably, the RF power supplied to the showerhead 40 ranges from 300 W to 4500 W. In the present embodiment, RF power of 1500 W is supplied to the showerhead 40.

While the showerhead 40 is being dry cleaned, the showerhead 40 may overheat due to the collision of ingredients of the activated cleaning gas and the inert gas with the showerhead 40. To prevent the showerhead 40 from overheating, the RF power can be discontinuously supplied to the showerhead 40. That is, the RF power can be alternately turned on and off several times.

To dry clean the showerhead 40, the cleaning gas can be sprayed via any one group of holes among the first spray holes 21, the second spray holes 22, and the gas curtain holes 33, and the inert gas can be sprayed via the remaining holes.

In step 4-4, since an undesired thin film that is separated from the showerhead 40 by the cleaning process of step 4-3 is deposited on the dummy wafer, the dummy wafer is unloaded from the wafer block 20.

In step 4-5, steps 4-1 through 4-4 are repeated at least twice so as to obtain a sufficient dry cleaning effect. Whenever steps 4-1 through 4-4 are performed once, the inside of the reactor 100 should be sufficiently purged and a used dummy wafer should be replaced with a new one.

Referring to FIG. 7, while the showerhead 40 is being cleaned or after the showerhead 40 is cleaned, the wafer block 20 is cleaned in step 4′. Step 4′ is similar to step 4 of cleaning the showerhead 40. After step 4-5 is performed, a subsequent dummy wafer is loaded on the wafer block 20 in step 4′-1. In step 4′-2, a pre-conditioning step, the flow rate and the pressures of the gases in the reactor 100 are stabilized by spraying an inert gas or a mixture of an inert gas and a cleaning gas in the reactor 100. Next, in step 4′-3, plasma is generated by supplying RF power to the wafer block 20 to activate a cleaning gas. The activated cleaning gas mostly cleans the wafer block 20 in the reactor 100. Thereafter, the dummy wafer is unloaded from the wafer block 20 in step 4′-4. Then, in step 4′-5, steps 4′-1 through 4′-4 are repeated at least once using new dummy wafers.

The reason for cleaning the wafer block 20 is given below.

While an ALD thin film is being deposited on a wafer W loaded on the wafer block 20 due to the first and second reaction gases, the ALD thin film is also deposited on an edge P of the wafer block outside a circumference of the wafer W, as shown in FIG. 8. If the ALD thin film deposited on the edge P of the wafer block 20 becomes thick, it is highly likely to peel off. Thus, step 4′ is additionally performed to remove the thin film deposited on the edge P of the wafer block 20 before it peels off. To perform step 4′, RF power of about 150 W to 2000 W is supplied to the wafer block 20.

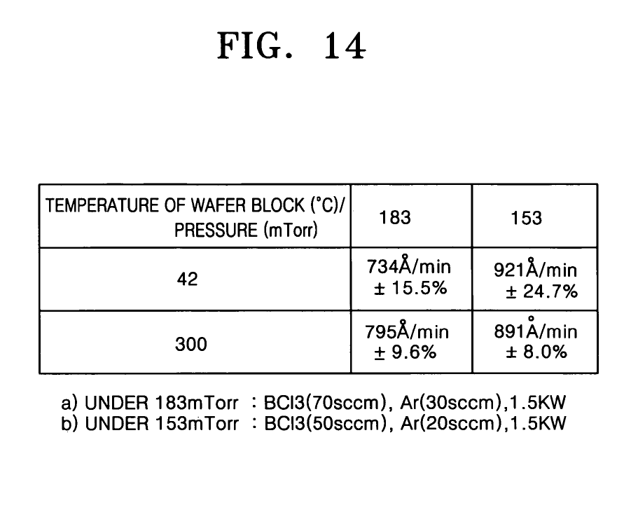

FIG. 14 is a table summarizing the etch rate and etch uniformity shown in FIGS. 9 through 13. Referring to FIG. 14, BCl₃ gas and Ar gas are supplied to the reactor 100 at a flow rate of 70 sccm and 30 sccm, respectively, and the reactor 100 is maintained under a pressure of about 183 mTorr. In this state, if RF power of 1.5 Kw is supplied to the showerhead 40, an Al₂O₃ thin film deposited on the showerhead 40 can be cleaned at an etch rate of 800 Å/min. If the wafer block 20 is also cleaned under the same flow rate and pressure conditions, when a wafer on which an Al₂O₃ thin film is deposited is loaded on the wafer block 20, the thin film can be etched at an etch rate of 200 Å/min. or less. The difference in the etch rate between the showerhead 40 and the wafer block 20 occurs because the RF power is supplied only to the showerhead 40.

In practice, a thin film is simultaneously etched from and redeposited on the wafer block 20. Thus, the deposited thin film is cleaned if the etch rate is higher than the redeposition rate, and a thin film sputtered from the showerhead 40 is coated on the entire surface of the wafer block 20 if the redeposition rate is higher than the etch rate. Thus, if a dry cleaning cycle is shortened, it is possible to omit step 4′ of cleaning the wafer block 20 under the above-described conditions, but the productivity may be slightly lowered.

The etch rate of the thin film on the showerhead 40 varies according to RF power, pressure conditions for cleaning, or temperature of the wafer block 20, and the variations will now be described with reference to FIGS. 9 through 11.

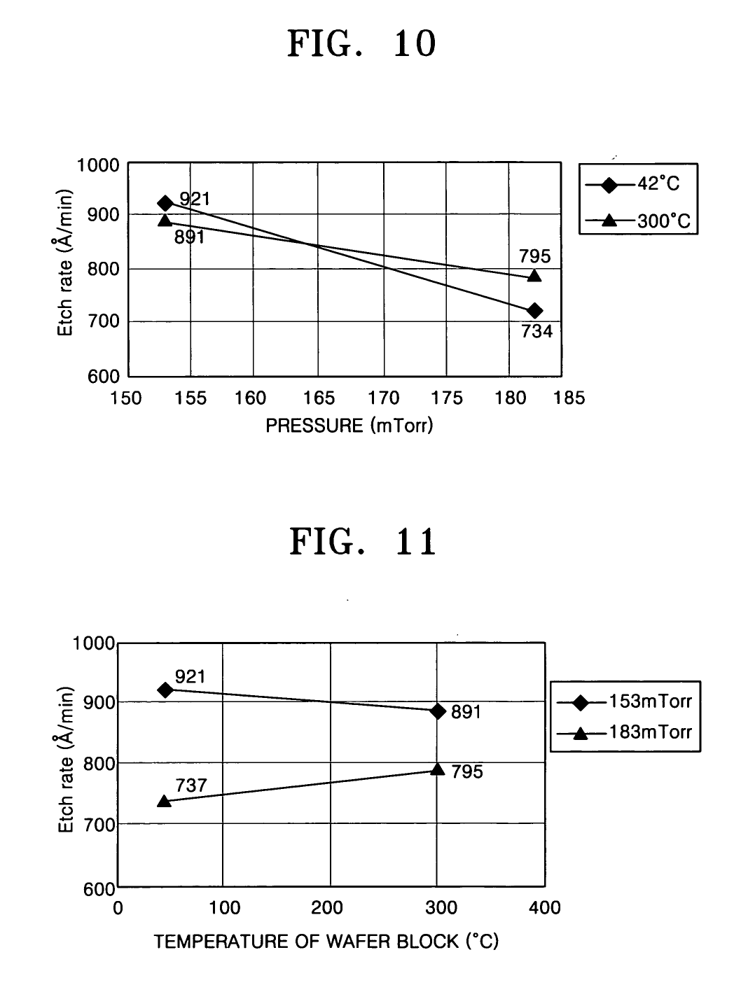

FIG. 9 is a graph showing the etch rate versus RF power supplied to the showerhead, FIG. 10 is a graph showing the etch rate versus the pressure of cleaning gas, and FIG. 11 is a graph showing the etch rate versus the temperature of the wafer block. Here, the etch rate is expressed in angstroms per minute (Å/min.), and the etched amount is the average of measurements obtained at five points of a top, a center, a bottom, a left, and a right of a bottom surface of the showerhead 40.

Referring to FIG. 9, as RF power supplied to the showerhead 40 increased from 1000 W to 1500 W, an etch rate of an Al₂O₃ thin film increased from 510 Å/min to 734 Å/min.

Referring to FIG. 10, as pressure for dry cleaning increased from 152 mTorr to 185 mTorr, when a temperature of the wafer block 20 was 42° C., an etch rate of the Al₂O₃ thin film decreased from 921 Å/min. to 734 Å/min., and when the temperature of the wafer block 20 was 300° C., an etch rate of the Al₂O₃ thin film decreased from 891 Å/min. to 795 Å/min.

Referring to FIG. 11, as the temperature of the wafer block 20 increased from about 40° C. to 300° C., when a pressure for dry cleaning was 153 mTorr, an etch rate of the Al₂O₃ thin film decreased from 921 Å/min. to 891 Å/min., and when a pressure was 183 mTorr, an etch rate of the Al₂O₃ thin film increased from 734 Å/min. to 795 Å/min. In view of the above-described measurements, it can be seen that the etch rate of the thin film was not directly proportional to the pressure for dry cleaning or the temperature of the wafer block 20. Thus, a variation in the temperature of the wafer block 20 does not greatly affect the etch rate of a thin film on the showerhead 40.

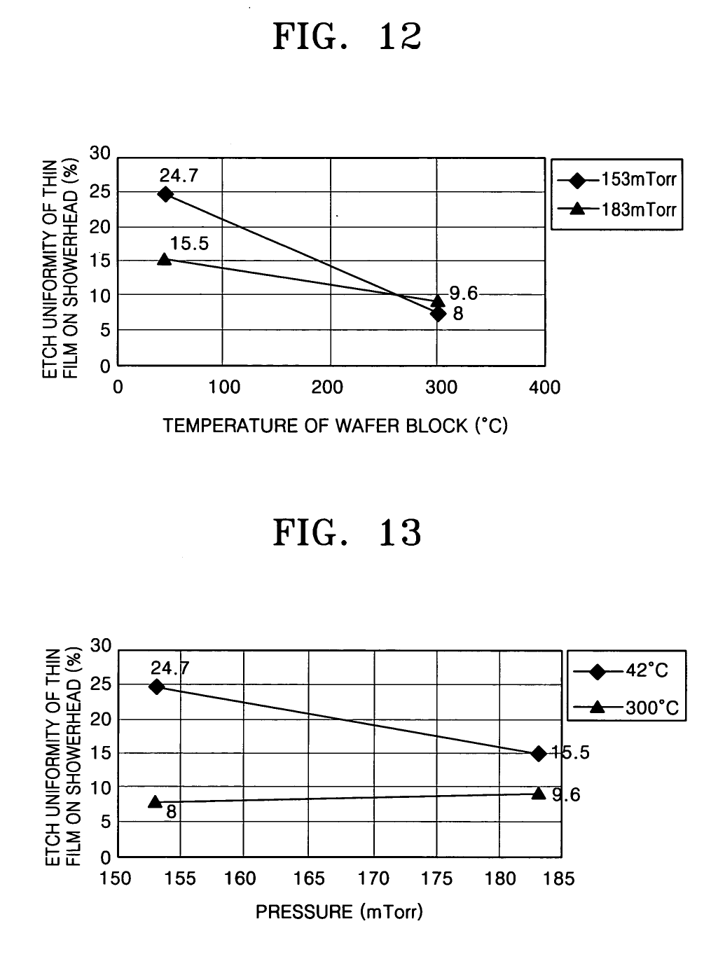

The etch uniformity of a thin film deposited on the showerhead 40 varies according to the temperature of the wafer block 20 or the pressure for dry cleaning, and this will now be described with reference to FIGS. 12 and 13.

FIG. 12 is a graph showing the etch uniformity versus the temperature of the wafer block, and FIG. 13 is a graph showing the etch uniformity versus the pressure of the cleaning gas. Here, the etch uniformity is expressed in a percentage (%) and the average of measurements obtained at five points on a top, a center, a bottom, a left, and a right of a bottom surface of the showerhead 40. The etch uniformity, i.e., the average of measurements can be obtained from 100×(maximum−minimum)/(2×average) (%).

Referring to FIG. 12, as the temperature of the wafer block 20 increased from about 40° C. to 300° C., when a pressure for dry cleaning was 153 mTorr, an etch uniformity of a thin film decreased from 24.7% to 8%, and when a pressure was 183 mTorr, an etch uniformity decreased from 15.5% to 9.6%.

Referring to FIG. 13, as pressure for dry cleaning increased from 153 mTorr to 183 mTorr, when the temperature of the wafer block 20 was 42° C., an etch uniformity of the thin film decreased from 24.7% to 15.5%, and when the temperature of the wafer block 20 was 300° C., an etch uniformity of the thin film increased from 8% to 9.6%. As can be seen from FIG. 13, when the temperature of the wafer block 20 was sufficiently high (i.e., about 300° C.), even if pressure for dry cleaning varied, a good etch uniformity of 10% or less was maintained. Thus, it can be inferred that the temperature of the wafer block 20 does not greatly affect the etch rate of a thin film on the showerhead 40, as described above, but is an important factor that improves the etch uniformity of the thin film on the showerhead 40.

Based on the above-described relationships between process conditions, when a thin film, e.g., an Al₂O₃ thin film, is deposited on the showerhead 40, the showerhead 40 can be dry cleaned at an etch rate of about 1000 Å/min.

In step 6, a pre-coating step, which is performed during a period between f0 and g, a preliminary thin film is formed to a sufficient thickness on an inner surface of the reactor 100 before the actual thin film is deposited. Step 6 is performed to firmly adhere particles remaining on the showerhead 40 or the wafer block 20 after the dry cleaned reactor 100 is purged and also to increase the deposition rate of a thin film on a subsequent wafer. An ALD thin film cannot be deposited on a wafer W at a normal deposition rate until a predetermined thin film is deposited on the showerhead 40. This pre-coating step can be performed at a higher speed than the deposition rate of the ALD thin film on the wafer W. For this, the time taken to purge the first and second reaction gases may be shortened, or the first and second reaction gases may be sprayed in the reactor 100 at the same time that chemical vapor deposition (CVD) is performed. The methods can enhance the productivity of equipment.

The pre-coating step (step 6) comprises a first pre-coating step performed before a dummy wafer is loaded and a second pre-coating step performed after the dummy wafer is loaded. The first and second pre-coating steps can be performed once or repeated several times. In the first pre-coating step, a thin film is deposited to a uniform thickness on the wafer block 20 such that heat generated from the wafer block 20 is effectively propagated to a wafer W. However, if the first pre-coating step is performed for an excessive amount of time, an overly thick film is coated on the wafer block 20 such that the temperature of the wafer W is undesirably lowered. In the second pre-coating step, a thin film is deposited to a sufficient thickness on the showerhead 40. After the pre-coating step (step 6) is performed, the process is returned to step 1 and repeated.

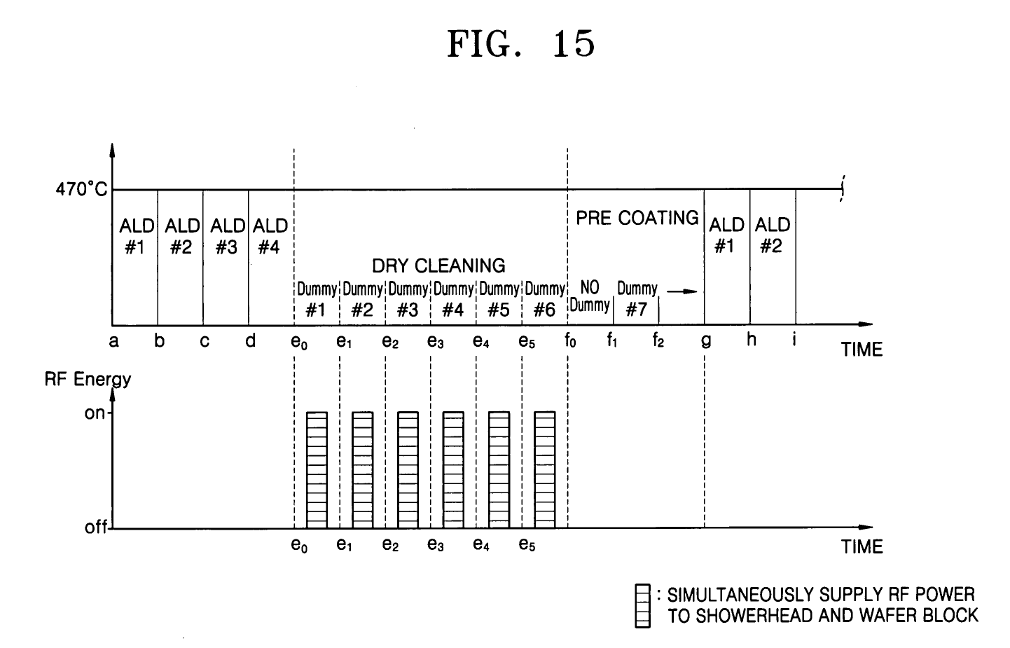

FIG. 15 is a graph showing a method of depositing thin films according to another embodiment of the present invention, which is performed in the thin film deposition apparatus shown in FIGS. 1 through 3. In the present embodiment, the same reference numerals are used to denote the same elements as those in the first embodiment.

Referring to FIG. 15, in a dry cleaning step, RF power is supplied to a showerhead 40 and a wafer block 20 at the same time. Thus, since the showerhead 40 and the wafer block 20 are simultaneously cleaned, the entire time taken for dry cleaning can be shortened.

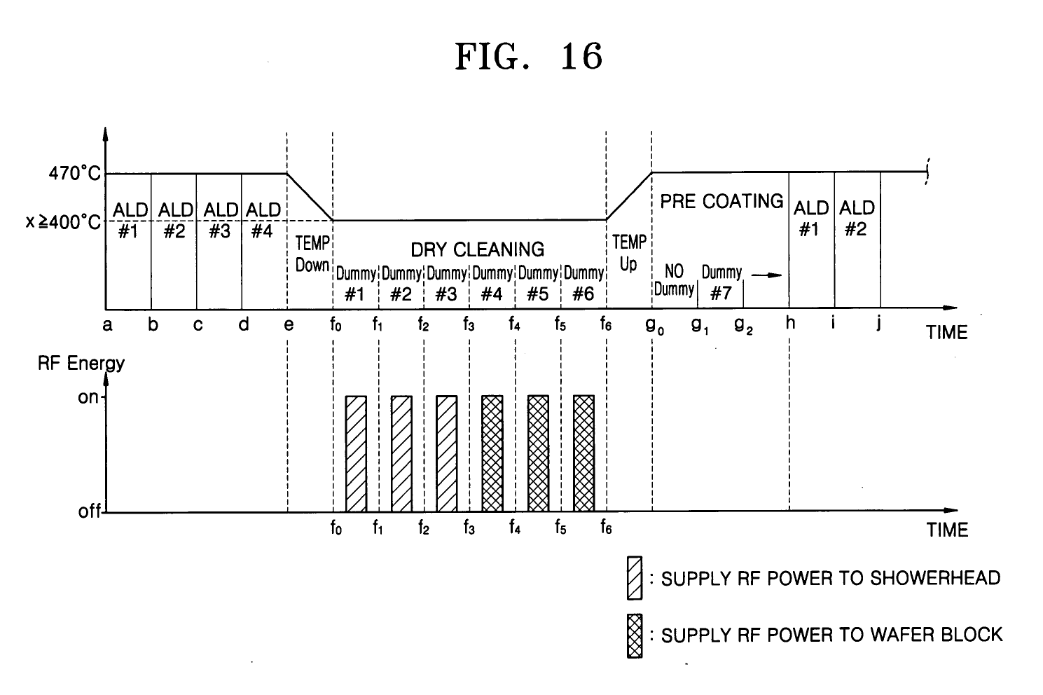

FIG. 16 is a graph showing a method of depositing thin films according to yet another embodiment of the present invention, which is performed in the thin film deposition apparatus shown in FIGS. 1 through 3, and FIG. 17 is a flowchart illustrating a process of cleaning a showerhead and a wafer block in the method shown in FIG. 16. In the present embodiment, the same reference numerals are used to denote the same elements as those in the first embodiment.

In the present embodiment, step 1 of loading a wafer W, step 2 of depositing an ALD thin film, and step 3 of unloading the wafer W are sequentially performed as in the first embodiment. Thereafter, in step 3.5, the temperature of a wafer block 20 is reduced lower than the temperature when the ALD thin film is deposited.

Next, a series of steps of cleaning a showerhead 40 and the wafer block 20 are performed. To clean the showerhead 40, steps 4-1 through 4-5 as described in the first embodiment are performed. Thereafter, the wafer block 20 is cleaned by performing steps 4′-1 through 4′-5 as described in the first embodiment, if necessary. In step 5′, a temperature of the wafer block 20 is raised from 400° C. or less to 470° C. and the inside of a reactor 100 is purged.

Next, byproducts generated from cleaning the showerhead 40 and/or the wafer block 20 is stuck to an inner surface of the reactor 100 in step 6, which is a pre-coating step.

As in the first embodiment, while an inert gas is being sprayed via a plurality of gas curtain holes 33, the ALD thin film is deposited in step 2. The ALD thin film is formed of one selected from the group consisting of Al₂O₃, HfO₂, and ZrO₂.

Also, to clean the showerhead 40, a cleaning gas is sprayed via any one group of holes among first spray holes 21, second spray holes 22, and the gas curtain holes 33, and the inert gas is sprayed via the remaining holes. Here, RF power supplied to the showerhead 40 ranges from about 300 W to 4500 W.

In step 4-3, to prevent the showerhead 40 from overheating, if the time taken for dry cleaning is relatively long, the RF power can be discontinuously supplied to the showerhead 40.

If step 4′-3 of cleaning the wafer block 20 is performed after the showerhead 40 is cleaned, step 4′-3 is performed on a new dummy wafer loaded on the wafer block 20. When the wafer block 20 is cleaned, RF power of about 150 W to 2000 W is supplied to the wafer block 20.

The pre-coating step (step 6) comprises a first pre-coating step performed before a dummy wafer is loaded and a second pre-coating step performed after the dummy wafer is loaded.

The cleaning gas is BCl₃ gas or a mixture of an inert gas and BCl₃ gas, and the inert gas is one of Ar gas and N₂ gas.

The BCl₃ gas is supplied at a flow rate of 5 sccm to 1000 sccm, and the inert gas is supplied at a flow rate of 5 sccm to 1000 sccm. The inside of the reactor 100 is maintained under a pressure of about 2 Torr or less.

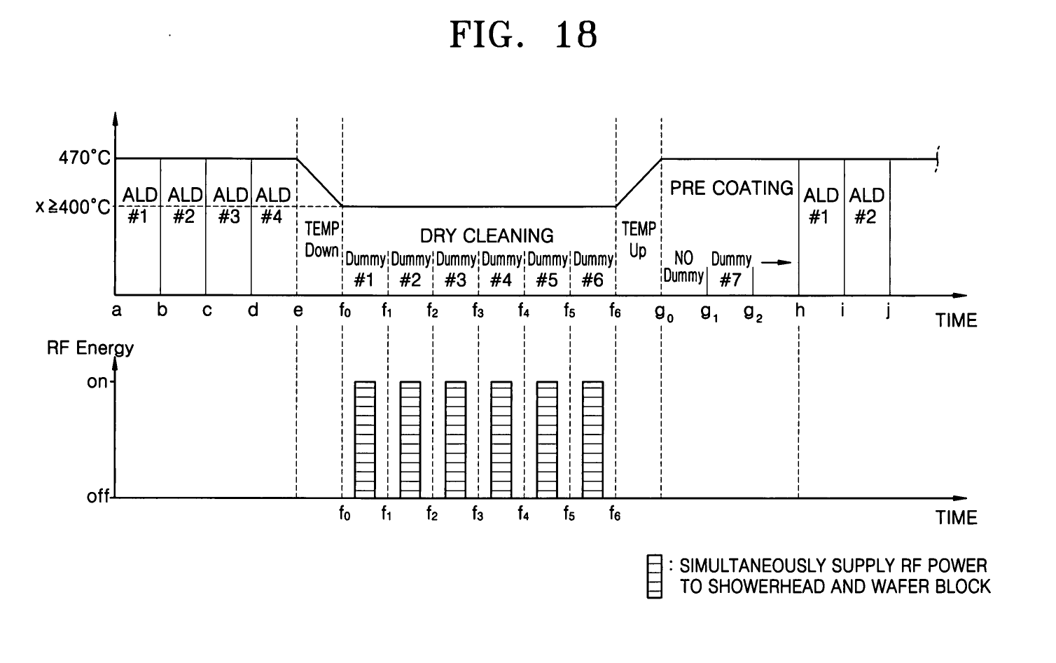

FIG. 18 is a graph showing a method of depositing thin films according to further another embodiment of the present invention, which is performed in the thin film deposition apparatus shown in FIGS. 1 through 3. In the present embodiment, the same reference numerals are used to denote the same elements as in the first embodiment.

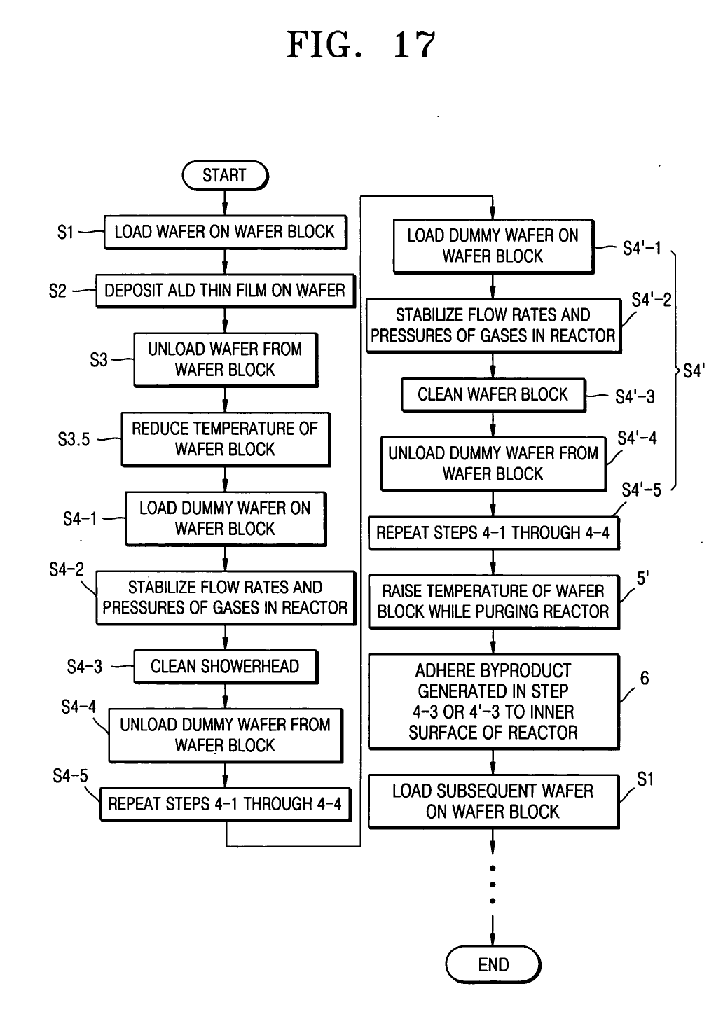

The present embodiment is the same as the third embodiment as described with reference to FIGS. 16 and 17 except that RF power is supplied to a showerhead 40 and a wafer block 20. Thus, since the showerhead 40 and the wafer block 20 are simultaneously cleaned, the entire time taken for dry cleaning can be shortened.

As described above, an ALD thin film formed of, for example, Al₂O₃, HfO₂, and ZrO₂, which is not sufficiently cleaned using conventional thermal dry cleaning, can be effectively cleaned without opening the reactor. Thus, productivity of semiconductor chips is improved.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed is:

1. A method of depositing an ALD thin film, the method being performed using a thin film deposition apparatus comprising: a reactor comprising a wafer block disposed in a chamber, the wafer block which heats a loaded wafer to a predetermined temperature, a top lid which covers and seals the chamber, a showerhead disposed under the top lid and combined with the top lid such that the showerhead is electrically isolated from the top lid, the showerhead including first spray holes and second spray holes, through which a first reaction gas and a second reaction gas are respectively sprayed on the wafer; and one or more RF power supply units which supply RF power to only the showerhead or both the showerhead and the wafer block, the method comprising:
(S1) loading the wafer on the wafer block;
(S2) depositing the ALD thin film on the wafer;
(S3) unloading the wafer, on which the ALD thin film is deposited, from the wafer block;
(S4-1) loading a dummy wafer on the wafer block;
(S4-2) stabilizing the flow rates and the pressures of gases in the reactor by spraying only an inert gas or a mixture of the inert gas and a cleaning gas in the reactor;
(S4-3) supplying RF power to the showerhead so as to activate the cleaning gas and mostly removing a thin film deposited on a surface of the showerhead by using the activated cleaning gas;
(S4-4) unloading the dummy wafer from the wafer block;
(S4-5) repeating steps 4-1 through 4-4 at least once using new dummy wafers; and
(S5) purging the inside of the reactor.

2. The method of claim 1, wherein the thin film deposition apparatus further comprises a plurality of gas curtain holes disposed on lateral surfaces of the showerhead or the top lid, the gas curtain holes which spray the inert gas toward an inner wall of the reactor,
wherein step 2 is performed while a gas curtain is being formed around the inner wall of the reactor by spraying the inert gas via the gas curtain holes.

3. The method of claim 1, wherein the thin film deposition apparatus further comprises a plurality of gas curtain holes disposed on lateral surfaces of the showerhead or the top lid, the gas curtain holes which spray the inert gas toward an inner wall of the reactor,
wherein step 4-3 is performed while the cleaning gas is being sprayed via any one group of holes among the first spray holes, the second spray holes, and the gas curtain holes, and the inert gas is being sprayed via the remaining holes.

4. The method of claim 1, wherein in step 4-3, the RF power is discontinuously supplied to the showerhead to prevent the showerhead from overheating.

5. The method of claim 1, wherein the RF power supplied to the showerhead ranges from 300 W to 4500 W.

6. The method of claim 1, further comprising (S4′-3) supplying RF power to the wafer block so as to activate the cleaning gas and mostly removing a thin film deposited on a surface of the wafer block by using the activated cleaning gas, wherein step 4′-3 is performed during or after step 4-3.

7. The method of claim 6, wherein when step 4′-3 is performed after step 4-3, step 4′-3 is performed after a new dummy wafer is loaded on the wafer block.

8. The method of claim 6, wherein the RF power supplied to the wafer block ranges from 150 W to 2000 W.

9. The method of claim 6, further comprising (S6) adhering byproducts generated in step 4-3 and/or step 4′-3 to an inner surface of the reactor,
wherein step 6 comprises:
a first pre-coating step performed before the dummy wafer is loaded on the wafer block; and
a second pre-coating step performed after the dummy wafer is loaded on the wafer block.

10. The method of claim 1, wherein the ALD thin film is formed of one selected from the group consisting of Al₂O₃, HfO₂, and ZrO₂.

11. The method of claim 1, wherein the cleaning gas is BC 13 gas or a mixture of an inert gas and BCl₃ gas, and the inert gas is one of Ar gas and N₂ gas.

12. The method of claim 11, wherein the BCl₃ gas is supplied at a flow rate of 5 sccm to 1000 sccm, the inert gas is supplied at a flow rate of 5 sccm to 1000 sccm, and the inside of the reactor 100 is maintained under a pressure of about 2 Torr or less.

13. A method of depositing an ALD thin film, the method being performed using a thin film deposition apparatus comprising: a reactor comprising a wafer block disposed in a chamber, the wafer block which heats a loaded wafer to a predetermined temperature, a top lid which covers and seals the chamber, a showerhead disposed under the top lid and combined with the top lid such that the showerhead is electrically isolated from the top lid, the showerhead including first spray holes and second spray holes, through which a first reaction gas and a second reaction gas are respectively sprayed on the wafer; and one or more RF power supply units which supply RF power to only the showerhead or both the showerhead and the wafer block, the method comprising:
(S1) loading the wafer on the wafer block;
(S2) depositing the ALD thin film on the wafer;
(S3) unloading the wafer, on which the ALD thin film is deposited, from the wafer block;
(S3.5) reducing the temperature of the wafer block to be lower than when the ALD thin film is deposited;
(S4-1) loading a dummy wafer on the wafer block of which the temperature is reduced;
(S4-2) stabilizing the flow rates and the pressures of gases in the reactor by spraying only an inert gas or a mixture of the inert gas and a cleaning gas in the reactor;
(S4-3) supplying RF power to the showerhead so as to activate the cleaning gas and mostly removing a thin film deposited on a surface of the showerhead by using the activated cleaning gas;
(S4-4) unloading the dummy wafer from the wafer block;
(S4-5) repeating steps 4-1 through 4-4 at least once using new dummy wafers; and
(S5′) raising the temperature of the wafer block to the same temperature as the temperature when the ALD thin film is deposited, while purging the inside of the reactor using the inert gas.

14. The method of claim 13, wherein the thin film deposition apparatus further comprises a plurality of gas curtain holes disposed on lateral surfaces of the showerhead or the top lid, the gas curtain holes which spray the inert gas toward an inner wall of the reactor,
wherein step 2 is performed while a gas curtain is being formed around the inner wall of the reactor by spraying the inert gas via the gas curtain holes.

15. The method of claim 13, wherein the thin film deposition apparatus further comprises a plurality of gas curtain holes disposed on lateral surfaces of the showerhead, the gas curtain holes which spray the inert gas toward an inner wall of the reactor,
wherein step 4-3 is performed while the cleaning gas is being sprayed via any one group of holes among the first spray holes, the second spray holes, and the gas curtain holes, and the inert gas is being sprayed via the remaining holes.

16. The method of claim 13, wherein in step 4-3, the RF power is discontinuously supplied to the showerhead to prevent the showerhead from overheating.

17. The method of claim 13, wherein the RF power supplied to the showerhead ranges from 300 W to 4500 W.

18. The method of claim 13, further comprising (S4′-3) supplying the RF power to the wafer block so as to activate the cleaning gas and mostly removing a thin film deposited on a surface of the wafer block by using the activated cleaning gas, wherein step 4′-3 is performed during or after step 4-3.

19. The method of claim 18, wherein when step 4′-3 is performed after step 4-3, step 4′-3 is performed after a new dummy wafer is loaded on the wafer block.

20. The method of claim 18, wherein the RF power supplied to the wafer block ranges from 150 W to 2000 W.

21. The method of claim 18, further comprising (S6) adhering byproducts generated in step 4-3 and/or step 4′-3 to an inner surface of the reactor,
wherein step 6 comprises:
a first pre-coating step performed before the dummy wafer is loaded on the wafer block; and
a second pre-coating step performed after the dummy wafer is loaded on the wafer block.

22. The method of claim 13, wherein the ALD thin film is formed of one selected from the group consisting of Al₂O₃, HfO₂, and ZrO₂.

23. The method of claim 13, wherein the cleaning gas is BCl₃ gas or a mixture of an inert gas and BCl₃ gas, and the inert gas is one of Ar gas and N₂ gas.

24. The method of claim 23, wherein the BCl₃ gas is supplied at a flow rate of 5 sccm to 1000 sccm, the inert gas is supplied at a flow rate of 5 sccm to 1000 sccm, and the inside of the reactor 100 is maintained under a pressure of about 2 Torr or less.
